(19) United States
(12) Patent Application Publication
(10) Pub. No.: US 2008/0272233 A1
(43) Pub. Date: Nov. 6, 2008

(54) Method and system for generating renewable energy

(76) Inventor: Kenneth F. Marlin, Belton, TX (US)

Correspondence Address: MAIER & MAIER, PLLC, 1000 DUKE STREET, ALEXANDRIA, VA, 22314, US

(21) Appl. No.: 11/797,101

(22) Filed: May 1, 2007

(51) Int. Cl. B64B 1/00; B64D 47/00; H01L 31/04

(52) U.S. Cl. 244/1 R; 244/30; 136/243

(57) ABSTRACT

A method, system and apparatus for the generation of energy. The method system and apparatus can include one or more airships that collect solar energy and convert it into electricity. An array of airships may be used so as to increase the collection rates of solar energy. The array of airships may include an airship that receives and stores electricity from the other airships in the array. Additionally, the solar energy may be transmitted to a terrestrial collection and distribution station.

### FIELD OF THE INVENTION

This invention relates generally to the collection of energy and more specifically to the collection of energy using solar collection devices disposed on airships.

### BACKGROUND

Various forms of energy are used throughout the world every day. Much of the energy is derived from the processing or burning of fossil fuels, such as coal, natural gas and oil. The generation of energy through the processing of fossil fuels, however, creates a significant amount of emissions. The emissions include carbon dioxide, which is also a greenhouse gas, as well as nitrogen oxides, sulfur oxides, heavy metals and volatile organic compounds. Carbon dioxide and other greenhouse gases may be leading factors in global warming.

Additionally, the obtaining and processing of fossil fuels requires a significant amount of time and money to achieve, while also impacting the environment. Many of the manners used to obtain fossil fuels, such as mining, are extremely harsh and cause significant damage on the environment that is mined.

Further, fossil fuels are a limited resource. By many indications, the amount of fossil fuels remaining to be extracted or collected is sharply decreasing. This decrease could cause the price for fossil fuels to increase sharply as the acquisition and processing of fossil fuels becomes more difficult.

There are, however, a variety of substitutes for fossil fuels, nuclear power and renewable energy sources. Nuclear power remains a tightly regulated field with extremely high barriers to entry and many well known concerns and problems. Further, in the United States, no new nuclear power plant has been opened since the early 1970s.

Renewable energy sources encompass a wide field, although sources related to solar rays, wind and water are the most common, most widely used and most practical. In the presently used formats, however, each of these sources of energy has significant drawbacks. Solar power is limited by the amount of sunlight an area is exposed to on a daily basis. Additionally, large urban centers often can not have a large solar panel array located proximately enough to the urban center to remain practical. Similarly, wind farms require extensive open areas with consistent wind in order to generate energy. Water power also faces similar limitations. Wind and water energy sources also present risks to the environment, such as hazards for migrating birds and fish, respectively.

### SUMMARY OF THE INVENTION

An embodiment of the invention includes a system and method for generating energy and reducing global warming.

In one exemplary embodiment, a method of generating renewable energy is described. The method can include launching a plurality of airships into the atmosphere and positioning the plurality of airships into a location. The method may also include coupling the plurality of airships and collecting solar energy through the use of a solar collection devices disposed on exterior portions of the plurality of airships. The method may further include converting the collected solar energy into electrical energy and storing the electrical energy.

In another exemplary embodiment, a system for generating renewable energy. The system may include at least one airship with a solar collection device. The at least one airship may be positioned in the atmosphere and may collect and store solar energy through the use of the solar collection device and a battery.

In yet another exemplary embodiment, a system for reducing global warming is described. The system may include means for launching a plurality of airships, as well as means for positioning the plurality of airships. The system may also have means for coupling the plurality of airships. Additionally, there may be a means for collecting solar energy in addition to a means for blocking solar rays. Further, the system can include means for converting solar energy into electrical energy and means for transferring the electrical energy into a terrestrial storage device.

### BRIEF DESCRIPTION OF THE FIGURES

Advantages of embodiments of the present invention will be apparent from the following detailed description of the exemplary embodiments thereof, which description should be considered in conjunction with the accompanying drawings in which:

FIG. 1 is an exemplary diagram of an airship.

FIG. 2 is an exemplary diagram of an array of airships.

FIG. 3 is an exemplary diagram of an array of airships positioned over a body of water.

FIG. 4 is an exemplary diagram of an airship that may collect and store electrical energy.

FIG. 5 is an exemplary diagram showing microwave transmission between remote locations.

FIG. 6 is an exemplary diagram showing a collection and storage of waste gases.

### DETAILED DESCRIPTION

Aspects of the invention are disclosed in the following description and related drawings directed to specific embodiments of the invention. Alternate embodiments may be devised without departing from the spirit or the scope of the invention. Additionally, well-known elements of exemplary embodiments of the invention will not be described in detail or will be omitted so as not to obscure the relevant details of the invention. Further, to facilitate an understanding of the description discussion of several terms used herein follows.

The word “exemplary” is used herein to mean “serving as an example, instance, or illustration.” Any embodiment described herein as “exemplary” is not necessarily to be construed as preferred or advantageous over other embodiments. Likewise, the terms “embodiments of the invention,” “exemplary embodiments” and “embodiments” do not require that all embodiments of the invention include the discussed feature, advantage or mode of operation.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form or any such embodiments may be described herein as, for example, “logic configured to” perform the described action.

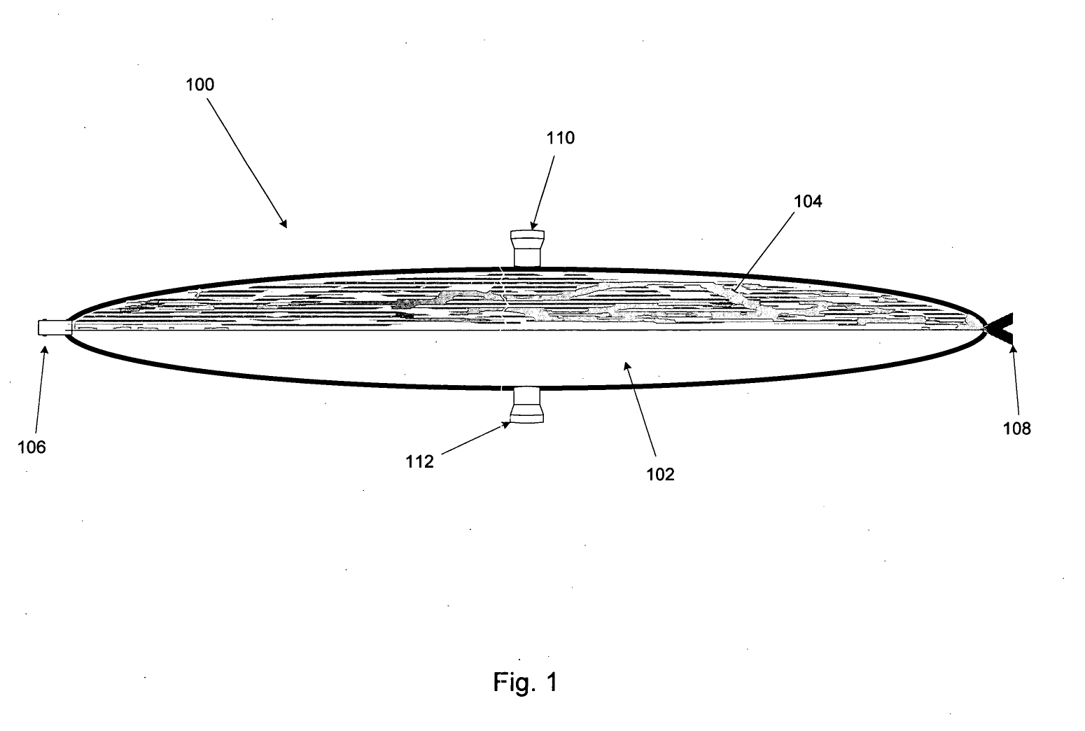

In one exemplary embodiment shown in FIG. 1, an airship 100 is described. Airship 100 may be substantially disc-shaped and may be filled with a gas so as to be lighter than air. In one exemplary embodiment, airship 100 may be substantially circular, disc-shaped or pancake-shaped and have a diameter or width of about 100 feet and a height of about 6 to about 10 feet. The shape and dimensions, however, may vary based upon the application for which airship 100 is being used. For example, in another embodiment, an airship having smaller dimensions and one or more retractable wings may be used. Here, after an airship is positioned in a desired location, the one or more retractable wings may be deployed and used in any of a variety of manners, such as those described below with respect to the exterior of airship 100. Further, in additional exemplary embodiments, the one or more retractable wings may be capable of being remotely deployed and retracted and may have a length of between twenty and fifty feet. The wings may also be deployed at any of a variety of lengths and orientations, in some embodiments, so as more efficiently use airship 100 in any of the embodiments described herein.

Additionally, in another exemplary embodiment, airship 100 may have an internal cavity 102 that may be filled with any gas, for example carbon dioxide (CO₂), emissions gas from a fossil fuel plant or any other gas or combination of gases known to one having ordinary skill in the art. Additionally, internal cavity 102 of airship 100 may be filled with enough gas, such as heated CO₂ or pressurized CO₂ or another gas or mixture of gases that is heated and/or pressurized, so that the weight of the materials constituting airship 100 would be less than the ambient air. In still other exemplary embodiments, airship 100 may be filled with a concentration that is part CO₂ and part some other gas. For example, the CO₂ and it accompanying weight may be offset with the addition of pressurized or heated air, helium, steam, ammonia, neon or methane or any other lighter than air gas known to one having ordinary skill in the art.

In another exemplary embodiment, airship 100 and internal cavity 102 may be made out of any of variety of materials. The material may be such that it can house CO₂ or any other gas at a variety of pressures without leaking for a predetermined amount of time. For example, the material may hold the CO₂ or other gas for a period of twenty to twenty five years. Additionally, the material may be disposed over a skeleton so that the shape of airship 100 may be formed. After the material is disposed over a skeleton of airship 100, interior cavity 102 of airship 100 may be filled with a volume of CO₂ or any other gas or mixture of gases. The CO₂ or any other gas or mixture of gases may further be pressurized to any desired pressure, for example 60 psi, so as to make the weight of airship 100 and its components less than that of air. Airship 100 may then be launched in any manner known to one having ordinary skill in the art and positioned at any of a variety of altitudes, for example at an altitude that is above any weather and above any air traffic while still remaining within the atmosphere of the earth, for example 50,000 to 60,000 feet.

In yet a further embodiment, a solar collection device 104 may be disposed on an exterior portion of the material on the outside of airship 100. For example, a solar collection paint or plastic or composite solar collection material that may be sprayed similar to paint may be disposed over the material on the exterior of airship 100. In yet another example, solar panels may be disposed over the exterior of airship 100. In any form known to one having ordinary skill in the art, solar collection device 104 may collect solar energy while disposed on airship 100. Solar collection device 104 may be disposed on all or part of airship 100. For example, solar paint may be sprayed on a top portion, for example a top half, of airship 100. In an alternative embodiment, solar collection device 104 may be disposed on one or more retractable wings of airship 100. Thus airship 100 could have a solar collection device 104 positioned or deployed in such a manner as to collect a maximum amount of available sunlight. Because the amount of available sunlight and the angle of the sun may vary based upon where airship 100 is located, airship 100 may also be positioned or oriented in various manners at times when sunlight is available so as to increase the potential for solar collection by solar collection device 104. For example an airship or array of airships could be tilted, for example using computer inputs on the pressure in the airship or array of airships, variations in the output of one or more solar heat pumps or any other means, so that the airship or array of airship may be tilted towards the sun. Thus the solar paint or solar panels may be positioned in a manner that is perpendicular or closer to perpendicular to the sun's rays, which may allow for the collection of more solar energy.

Additionally, any solar collection device 104 disposed on or associated with airship 100 may be coupled with a solar battery or converter. The solar battery or converter may be used to transform solar energy into electrical energy. For example, if solar collection device 104 includes photovoltaic cells or any other solar power device known to one having ordinary skill in the art, electrical energy may be made and then stored using the solar battery or converter. Also, the solar battery or converter may be disposed in any of a variety of positions on or within airship 100. For example, it may be desirable to dispose the solar battery or converter proximate solar collection device 104, proximate a solar heat pump or engine, or in any other location that may be advantageous.

In another exemplary embodiment, two or more airships may be deployed at a desired altitude and coupled together. In this exemplary embodiment, airship 100 may have a both a cable 106 and a coupling mechanism 108. Cable 106 may be anchored at a front portion, or any other portion, of airship 100. Cable 106 may be such that it is fully retractable into an interior portion of airship 100 and may be extendable to any desired length, for example about one hundred feet. Cable 106 may be made out of any material known to one having ordinary skill in the art that may be stored and deployed in any known manner. Additionally, cable 106 may be strong enough to be tethered to another airship at any desired altitude and be capable of remaining tethered at a desired distance from another airship without cable 106 breaking, stretching outside of a desired range or flexing outside of a desired range. Cable 106 may further be employed to couple a first airship to a second airship for an extended amount of time, for example several years. Additionally, cable 106 may further include an interior portion for housing electrical wires capable of transmitting electricity from one airship to another airship.

In another exemplary embodiment, microwave power transmission may be used to transmit electricity between two airships, such as between two airships that are collecting solar power or an airship that is collecting solar power and another airship that is acting as a storage device for large amounts of electrical energy. For example, a first airship may have a microwave power transmitter disposed thereon. In one exemplary embodiment, a microwave power transmitter may be located near or integrated with cable 106 or coupling mechanism 108 used to couple one airship to another. In another exemplary embodiment, one or more microwave transmitters may be located at different portions of airship 100, for example at about a top, center position with microwave transmitter 110 and/or about a bottom, center position as in microwave transmitter 112.

In a further exemplary embodiment, airship 100 may have a rectenna, disposed thereon. A rectenna may be a form of antenna, such as a rectifying antenna, that is capable of receiving microwave transmissions and converting the microwave transmission into electricity. A rectenna may be located on any part of airship 100 whereby the rectenna could receive microwave transmissions. In some exemplary embodiments, a rectenna may be implemented with or located near cable 106, coupler 108, microwave transmitter 110 or microwave transmitter 112.

In a further exemplary embodiment, cable 106 disposed on airship 100 may be remotely deployed. For example, cable 106 may be deployed electronically via a remote control located on another airship, an airplane or from a terrestrially-located control station. Cable 106 may be deployed to any desired length and may connect to another airship via coupling mechanism 108, as described above. Coupling mechanism 108, which may be disposed at a rear portion of airship 100 or any other desired position, may act to receive cable 106 and securely couple the first airship that deploys cable 106 with the second airship that accepts cable 106. A first airship and a second airship may then be able to be positioned at any desired distance from each other that is desired. In addition, the first airship and the second airship may be remotely uncoupled and separated, if desired, and cable 106 from the first airship may be retracted to the first airship.

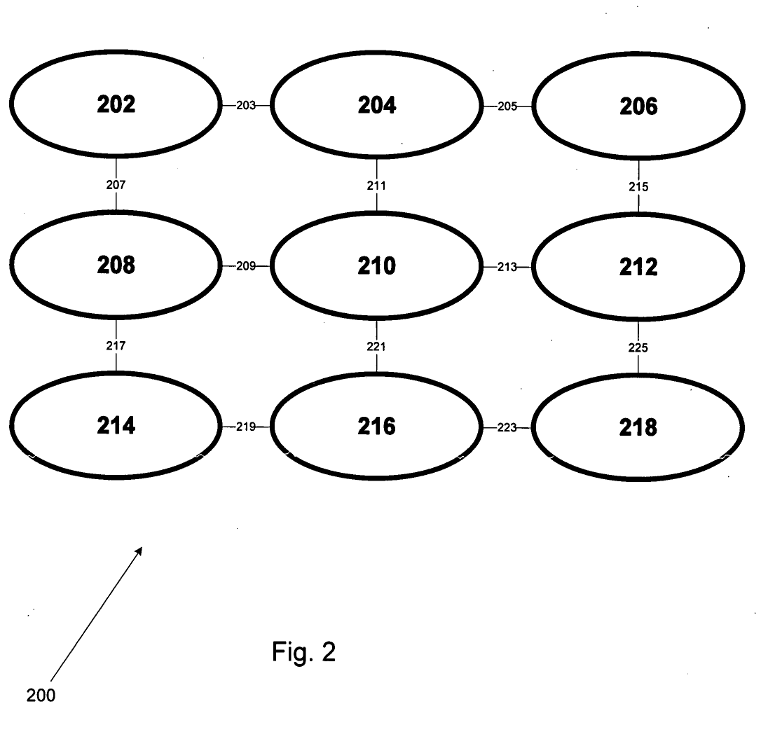

In yet another exemplary embodiment, as shown in FIG. 2, there may be any number of locations on an airship from where a cable may be deployed. Additionally, a plurality of cables similar in function to those described above may be used on a first airship, e.g. airship 202 to connect the first airship to a corresponding plurality of airships, such as airships in array 200, having a plurality of coupling mechanisms. For example, a first airship 202 may have a first cable 207 that may be deployed from a first position at the front of the first airship and a second cable that may be deployed from a port position on first airship 202. The second airship 208 may have a corresponding coupler at the rear portion of second airship 208 and a couple at a starboard position of second airship 208. Additionally, in a further exemplary embodiment, every airship may have both one or more cables that may be deployed and one or more couplers for receiving cables. Some exemplary airships may further have positions for receiving and deploying cable that mirror other exemplary airships while still other exemplary airships have positions for receiving and deploying cable that correspond with other exemplary airships.

Thus, in a further exemplary embodiment shown in FIG. 2, any number of airships may be coupled using cables deployed from airships and couplers disposed on airships. For example, a string of any desired number of airships, such as airship 202, airship 204 and airship 206, may be coupled whereby a first airship deploys cable 203 from a front position that is coupled to a coupler at the rear of second airship 204. Second airship 204 may also be coupled to third airship 206 through the use of cable 205 deployed from a front position of second airship 204 to a coupler at the rear of third airship 206. Third airship 206 may then be coupled to a fourth airship in a similar manner and a fourth airship may be coupled to a fifth airship in a similar manner, and so on until the desired number of airships are connected. Additionally, the distance between airships coupled together in the string formation may be changed so that each airship may be any desired distance from any airship to which it is coupled.

In a further exemplary embodiment, a field or two-dimensional array of airships, such as array 200, may be formed by coupling airships in string formation, as described above, and then by coupling airships positioned to the left and right or port and starboard sides of each other. For example, as described above, a first string of airships, such as a string formed by coupling airships 202, 204 and 206, may be formed. Then, to the starboard side of the first string of airships, a second string of airships may be formed. For example, airship 208 may be coupled airship 210 using cable 209 and airship 210 may be coupled to airship 212 using cable 213. A third string of airships may then be formed to the starboard side of the second string of airships, for example coupling airship 214 to airship 216 using cable 219 and coupling airship 216 to airship 218 using cable 223. Additional strings of airships may be formed until the desired number of strings is formed. These strings of airships may be formed such that they form a field that remains in position through the use of a propulsion apparatus, as described below. Alternatively, the strings may be coupled to each other. If the strings are to be coupled to each other, the first airship in the first string, e.g. airship 202, may be connected via a cable, e.g. cable 207, extending from the starboard side of the first airship in the first string to a coupler in the port side of the first airship in the second string, e.g. airship 208. Airship 208 may then couple with the first airship in the third string, e.g. airship 214, through the use of a cable, e.g. cable 217, extending from the starboard side of the first airship in the second string and connecting to a coupler on the port side of the first airship in the third string. The first airship in the fourth string (not shown) may then be coupled to the first airship in the third string in a similar manner and so on. Further, a similar coupling scheme may be used for each airship in each string, such that, for example, the second airship in the first string is connected to the second airship in the second string, the second airship in the second string is coupled to the second airship in the third string and so on until the desired airships are coupled and a field having the desired surface area of airships is formed. For example, airship 204 may couple to airship 210 using cable 211, airship 210 may couple to airship 216 using cable 221, airship 206 may couple to airship 212 using cable 215 and airship 212 may couple to airship 218 using cable 225. Any number of additional airships may be coupled to any other number of airships to produce an array of any desired size. Further, similar to the above exemplary embodiment of the string formation, the distance between any two, three or four airships that are coupled in array 200 may be varied so as to achieve any desired distance between any two airships.

In both the string formation and the array 200 formation, a plurality of airships may be positioned or repositioned in any of a variety of manners. In one exemplary embodiment, the string of airships or array 200 of airships may be repositioned by remote control and utilizing propulsion mechanisms associated with each individual airship. For example, when altitude, tilt angle or lateral orientation changes need to be made, a control station may input the desired changes in position or coordinates and each airship in the string formation or in the field formation may utilize their individual propulsion mechanisms to achieve and maintain the desired position. In a different exemplary embodiment, if other changes in position are desired, an airship at a leading or trailing edge of the string formation, or an airship located on an exterior portion of a field formation, may be coupled with an aircraft. The aircraft may then tow the string formation or field formation of airships to a desired location before decoupling with the string formation or the field formation. The aircraft may be, for example, a Harrier Jump Jet, a dirigible or a propeller aircraft that is capable of achieving altitudes above 50,000 feet. If smaller positioning changes are desired after the string or field formation of airships is decoupled from the towing aircraft, the changes may be made via remote control and any propulsion devices associated with an airship.

In a different exemplary embodiment, an array of airships 200 may be created, as described above, but greater distances may be used between the individual airships. For example, two airships in array 200 may be separated by several hundred or several thousand feet. Additionally, a high strength, flexible and/or stretchable mesh or other material may be disposed between the airships. Further, the mesh or other material may be coated with a solar paint or have solar collecting capabilities. Thus, in this example, an array of airships may constitute fewer airships, but an amount of solar energy harvested or amount of solar rays that may be blocked would not be affected.

After a plurality of airships are connected in string or field formation, their positioning may be such as to collect solar energy and prevent some solar rays from reaching Earth, as described in greater detail below. As in FIG. 1, solar collection device 104, such as solar paint or solar panels disposed on a portion of each individual airship, may be used to collect solar energy in any manner known to one with ordinary skill in the art. The collected solar energy may be transmitted to a solar battery or converter in airship 100 and the solar energy may be converted from solar energy into electrical energy. The electrical energy may then be distributed to any of a variety of locations or mechanisms. For example, part of the electrical energy may be sent to a pump that can regulate the pressure of the any gas inside airship 100; part of the electrical energy may be sent to a propulsion mechanism; part of the electrical energy may be sent to a cable extending and retracting mechanism; part of the electrical energy may be sent to a coupling mechanism; part of the electrical energy may be sent to a data transmitting and receiving mechanism; part of the electrical energy may be sent to another airship; part of the electrical energy may be sent to a storage device for electrical energy; and part of the electrical energy may be sent to any other desired location.

In yet another exemplary embodiment of an airship, a pump may be disposed on an interior portion of airship 100. The pump may provide any of a variety of functions, for example regulating the pressure of the CO₂ or other gas or gasses inside airship 100, provide heat for the interior of airship 100, and provide propulsion for airship 100. The pump may be located in any interior portion of airship 100, for example proximate cable 106 or coupling mechanism 108.

Internal cavity 102 of airship 100, the pressure of the gas or gases used to keep airship 100 aloft may vary due to time, temperature, the ambient air pressure around airship 100 and any other known factors. Thus, a pump, such as a solar heat pump, may be used to maintain a desired pressure in an airship. The pump may be any type of heat pump, and may include both heat pump and air compressor qualities. The pump may receive electric power from a solar battery or converter. The pump may also be located in any desired location in the interior of airship 100. In some exemplary embodiments, the pump could be located proximate the solar battery or converter. The pump may then increase the pressure inside airship 100 by adding any additional desired gas to the internal cavity 102 of airship 100. For example, in some exemplary embodiments, the pump may be connected to an opening, such as a port, disposed on a wall of an airship. The opening or port may be located on any portion of airship 100 and may be connected to the pump using any means known to one having ordinary skill in the art, for example rubber, plastic or metallic tubing. The opening or port may open to the outside of an airship, allowing for the exchange of gases between the interior of airship 100 and the ambient gases outside airship 100. Thus, the pump may be able to vary the pressure or temperature in airship 100 by regulating the opening and closing of an opening or port and/or by varying the composition or mixture of gases in internal cavity 102.

The pump in airship 100 may also include a variety of features used to regulate various aspects of airship 100. For example, the pump may include sensing capabilities for sensing ambient conditions within airship 100. Thus, in one embodiment, the pump can include a pressure sensor for monitoring the internal gas pressure of an airship. Further, if the pump senses that the pressure in an airship is too high or too low, it may decrease or increase the pressure accordingly. Further, the pump may include a temperature gauge that can monitor the Internal temperature of internal cavity 102 of airship 100. For example, a temperature that is too high may cause an undesired increase of the pressure in airship 100. Alternatively, a temperature that is too low may create an environment where there is not enough pressure in airship 100. Thus the pump may have the capability to increase the temperature, for example using a heated gas, if the temperature is too low. If the temperature is too high, the pump may have the capability to decrease the temperature, for example, by pumping cooler gas into airship 100.

A solar pump may also provide propulsion to airship 100, while maintaining its ability to regulate gas pressure within airship 100. The pump may include two or more pipes that exit airship 100, for example at a rear portion of airship 100, proximate coupling mechanism 108. The pipes may be designed such that pressurized gas may be fed through the pipes and out of airship 100, thereby moving airship 100. In one exemplary embodiment, a pair of pipes may exit the rear of airship 100 in a Y-formation. Thus, when pressurized gas is fed through both of the pipes, airship 100 may be propelled forward. However, if it is desired to turn airship 100 in a direction, pressurized gas may be fed through only one of the tubes. Thus, if it is desired to turn airship 100 to port, gas may be fed through the starboard pipe and if it is desired to turn airship 100 to starboard, gas may be fed through the port pipe. Using this propulsion system, airship 100 may be moved to any location or positioned in any orientation. The propulsion system may also be controlled in any manner, for example via remote control from an airborne or terrestrial control station, as described herein.

In another exemplary embodiment, the propulsion generated by a solar pump may be used for precise maneuvering of airship 100. Slight or precise adjustments in the position, location and orientation of airship 100 may be performed through the use of the pump. For example, when coupling a first airship to a second airship, slight adjustments may be made through the use of the heat pump to properly orient and position the first and second airships so that they may properly couple. Controls for precise movements of an airship may be made in any manner, such as by remote control. Additionally, precise movements may be controlled by a computer so as to allow for extremely precise inputs.

In a further exemplary embodiment, airship 100 may have an individual identification or communication device so that it may be individually identified or controlled when in an array 200. For example, a radio frequency identification (RFID) tag may be disposed on a portion of each airship. Any RFID tag may be either active or passive and contain a microchip. The microchip may contain information such as an identifier, such as a serial number, for airship 100 to which the RFID tag is disposed. Further, the RFID tag may contain information about the intended location or function of airship 100. The RFID tag may further be able to communicate with a user or operator located at a remote location, such as at an airborne or terrestrial control station. Any individual identification or communication device may also be coupled with a receiver so that any form of remote control may be performed.

In yet a further exemplary embodiment, each airship that may be connected in an array 200 may include a device that allows the specific location of airship 100 to be determined. For example a global positioning system (GPS) transmitter may be disposed anywhere on airship 100. The GPS transmitter may further be capable of communicating with any remote control device and any propulsion device on airship 100. The GPS transmitter may also be capable of communicating with a remotely located device so as to allow for a user or operator to know or determine the position, location, altitude or other placement position of airship 100. Any GPS device disposed on airship 100 may further be capable of assisting an operator, human or computerized, in positioning airship 100, orienting airship 100 or otherwise moving airship 100.

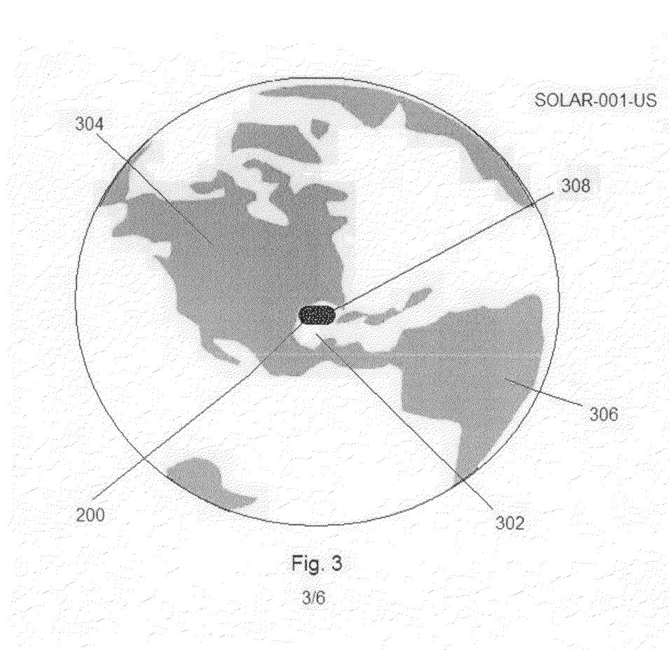

In another exemplary embodiment, a string or array 200 of airships could be coupled to serve any of a variety of functions. As described above, a string or array 200 of airships can be made at a predetermined altitude. The string or array 200 can include any number of airships, ranging from two to several million or more airships. In one exemplary embodiment, the solar collection devices disposed on airships in array 200 may be used to harvest solar power. Array 200 may be such that they are above any weather or any clouds and may therefore have the ability to collect solar energy throughout daylight hours. Array 200 may also be positioned in any location. For example, in FIG. 3, which presents a view of Earth, array 200 is positioned above Gulf of Mexico 302, generally between North America 304 and South America 306. Array 200 may be an array of any size, for example an array of a few airships to an array of several million or more airships. Any solar energy collected by any solar device disposed on the airships 308 in array 200 could be transmitted to a solar battery disposed inside the individual airships 308. The solar battery could convert the solar energy into electrical energy and distribute the electrical energy to any of a variety of locations. For example, some electrical energy could be sent to a solar heat pump so as to provide power for the pump. Other electrical energy could be transmitted to another airship via an electrically conductive cable or via microwave transmission, following the conversion of the electricity into microwaves, as described above.

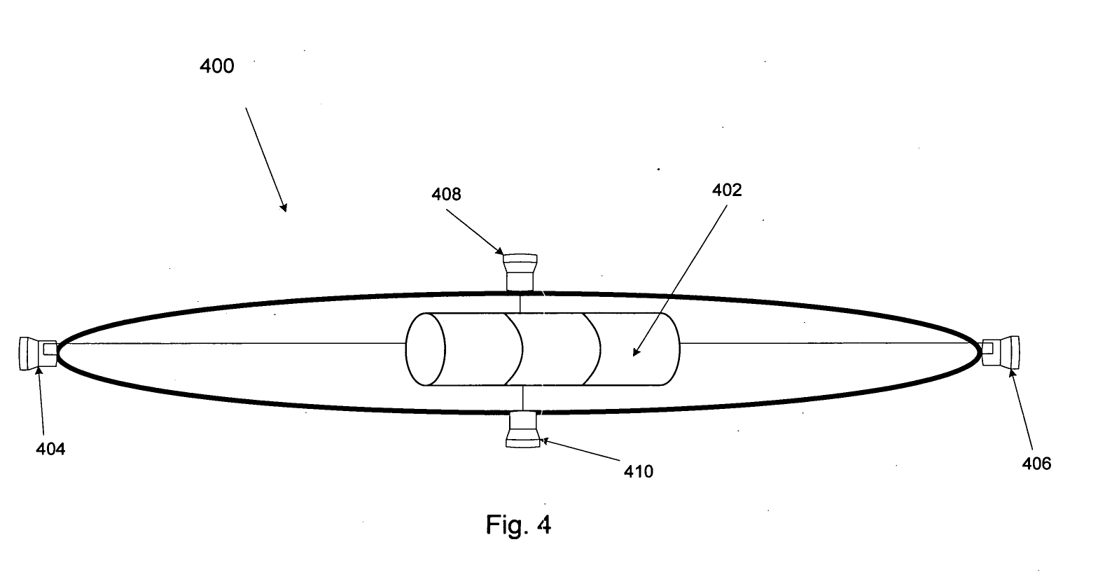

Following the transmission of any electricity from a first airship to a second airship in array 200, the second airship may transmit the electricity to a third airship in array 200. Alternatively, the second airship may transmit the electricity to a collection and storage device, such as a collection and storage device as shown in FIG. 4. The collection and storage device could be any device used to collect and store electrical energy. Collection and storage airship 400 may have any number of microwave transmitters and receivers (e.g. rectennas), for example microwave transmitter and receivers 404, 406, 408 and 410. The collection and storage device 402 may be disposed on or in another airship, for example collection airship 400. Collection and storage airship 400 may be similar in structure to airship 100 described previously or may be of any size or any other type of airship or aircraft to which microwave transmissions may be reliably made. In another exemplary embodiment, collection and storage device 402 may be positioned on an underside of collection airship 400. Thus, in this embodiment, collection and storage device 402 may be positioned, suspended or attached similar to a canopy on a standard airship or dirigible. Collection and storage device 402 may further include a plurality of batteries, for example lithium-ion batteries capable of storing large amounts of energy.

Electrical energy may be stored in the collection and storage device 402 may be stored for a predetermined time and then transmitted to a terrestrial collection and storage device or a satellite having a collection and storage device using a microwave transmitter, for example transmitter 404, 406, 408 or 410, or a microwave transmitter located anywhere else on airship 400, as explained in further detail below. The electrical energy in the collection and storage device 402 may be transmitted to the terrestrial collection and storage device at any predetermined time and using any method known to one having ordinary skill in the art, such as microwave transmission. The electric energy may then be distributed from the terrestrial collection and storage device in any manner desired.

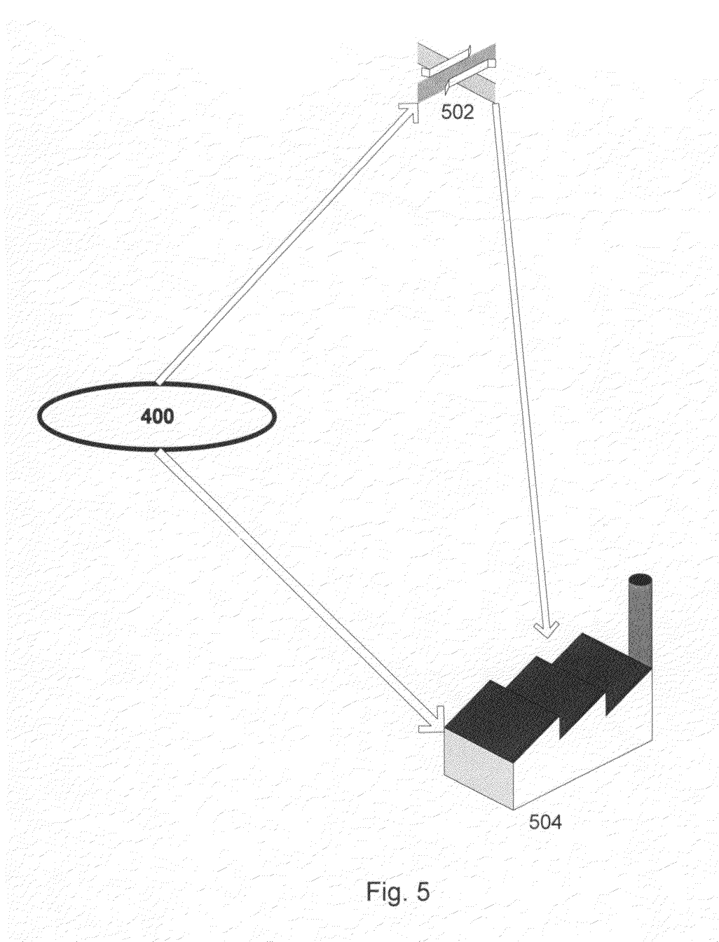

In alternative exemplary embodiments, a microwave transmitter may be used to transmit energy to any other desired location capable of receiving microwave transmissions. For example, a variety of airships, for example airships in array 200, could transmit microwaves to collection and storage airship 400. Collection and storage airship 400 may be such that any number of other airships could transmit microwaves thereto. The collector airship may also include collection and storage device 402 capable of storing electrical energy after microwave transmissions are received by a collection and storage airship 400—mounted rectenna or rectennas and converted to electrical energy. Collection and storage airship 400 may store any amount of electrical energy. Additionally, the electrical energy stored in collection and storage airship 400 may be accessed in any of a variety of manners. For example, as shown in FIG. 5, the collection and storage airship 400 could use microwave power transmission to transmit the power to a terrestrially-located rectenna at a terrestrial power storage facility 504. Collection and storage airship 400 could alternatively transmit, for example using microwaves, the stored electrical energy to a satellite 502 capable of receiving and storing electricity that is transmitted by microwaves. In one example, satellite 502 may be capable of storing greater amounts of electricity than the collection and storage airship 400 and may be capable of transmitting the stored electricity to a terrestrially-located rectenna and power storage facility 504.

In yet another alternative embodiment, collection and storage airship 400 could be retrieved from its position proximate the other airships in array 200 after receiving a predetermined amount of microwave transmissions or after it has been deployed for a predetermined amount of time. This retrieval could be accomplished in any of a variety of manners. For example, collection and storage airship 400 could be retrieved using a remote control to control a propulsion device, such as a solar heat pump or any other propulsion device, located on collection and storage airship 400 and pilot the collection and storage airship 400 to a desired location. The remote control may also include functionality to regulate the pressure and altitude of collection and storage airship 400, similar to the functionality described with respect to the other airships, for example airship 100. As another example, collection and storage airship 400 could be tethered to another aircraft, for example a Harrier Jump Jet, and towed to a desired location in any manner known to one having ordinary skill in the art. Collection and storage airship 400 may then be deposited at a desired location, for example power storage facility 504 or it may be untethered and piloted to a desired location via remote control, as described previously.

In yet another exemplary embodiment, array of airships 200 may be used to block solar rays from penetrating the atmosphere. For example, array of airships 200, could be arranged in a formation, similar to that shown in FIG. 3, that could block a percentage of solar rays from reaching Earth. Each airship in array 200, though the use of the solar collection device that may be disposed on thereon, e.g. solar collection device 104, may absorb solar rays that would otherwise travel through the atmosphere to the surface of Earth 306. These solar rays, which may assist in causing the phenomenon known as “global warming”, could therefore be prevented from heating and of land, water or the surrounding air. The array of airships could be positioned in any location so as to prevent some of the solar rays from heating that area. For example, if it was desired to cool the Gulf of Mexico 302 by a certain temperature, an array of airships 200 could be positioned over a portion of the Gulf of Mexico 302. Thus, fewer solar rays would contact the water in the Gulf 302, and the overall temperature of the Gulf 302 could be lowered. This lowering of temperature could produce several results, including a partial lowering of the overall global temperature on Earth 306 and a resultant reduction in global warming. Array of airships 200 may be positioned in any location, however, and therefore allow for the reduction of solar rays contacting the area of land or water below the array. In another example, an array of airships may be positioned over portions of polar ice cap that have previously melted. Before portions of the polar ice cap melted, sunlight and solar rays were largely reflected off of the ice cap and not absorbed into the white, reflective ice and snow. However, with the melting of the ice cap and the snow and ice receding, leaving more water exposed, solar rays are absorbed by the darker water. This absorption of solar rays can lead to the increase in temperature of the water and may cause additional melting of the ice and snow. However, if array of airships 200 were to be positioned over areas of the polar ice cap that had previously melted, array of airships 200 could absorb a portion of the solar rays and there could be fewer solar rays for the exposed water to absorb. Consequently, the temperature of the water could be lowered, which may prevent the further melting of ice and snow and may allow for the increase in the level of ice and snow at the ice cap.

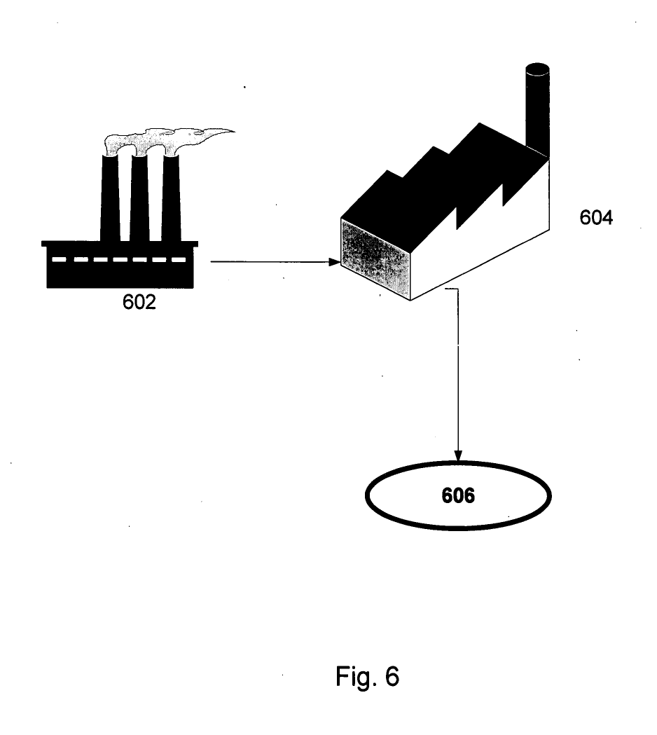

In yet another exemplary embodiment shown in FIG. 6, CO₂ and other gases, for example greenhouse gases, may be harvested for use in airships, e.g. airship 100. It is well known that fossil fuel-burning plants, such as power plants, emit a variety of emissions. One of the more significant emissions is CO₂, which is contained with a variety of other substances, such as carbon, sulfur oxides, nitrogen oxides, and some low-level radioactive substances. In this exemplary embodiment, instead of releasing these emissions into the environment as is commonly done, these emissions may be collected at fossil fuel plant 602 and piped or otherwise sent to a processing facility 604. In one exemplary embodiment, the emissions may be harvested directly from an exhaust vent at fossil fuel plant 602. At processing facility 606, potentially useful substances may be removed from the emissions. For example, carbon and sulfur in the emissions may be filtered or otherwise collected and distributed to be used in any manner known to one having ordinary skill in the art. Alternatively, the emissions may be collected and stored in an unfiltered state.

Further, the CO₂ and other greenhouse gases contained in the emissions may be separated and stored or may be stored in unfiltered form, as described above. Because a significant amount of CO₂ and other greenhouse gases are contained in these emissions, a large amount of CO₂ and other gases may be collected and stored at processing facility 604. The collected CO₂ and other emissions gases may then be sent to one or more facilities associated with the manufacture and/or launching of grounded airship 606. The CO₂ and other gases may be stored at these facilities in any manner known to one having ordinary skill in the art, for example in storage tanks. The stored CO₂ and other gases may then be pumped into airships at appropriate levels of pressure to achieve loft, and allowing an airship to fly. Thus, various mixtures of gases may be used within the airships. In some embodiments, the concentration of gases may include a known quantity of CO₂ and a known quantity of another gas. In other exemplary embodiments, collected emissions gases from the fossil fuel plant 602 may be captured, stored and pumped into airships without any filtration.

It should be noted that many other embodiments and uses for airships in various states, orientations and locations are envisioned. For example, many different tasks or functions may be performed by an airship or array of airships both while the airship or airships are executing one task or function described previously as well as at other times. These tasks or functions may include security and surveillance, such as border control, search and rescue, weather observation, electronic signal relay, communication signal relay, disaster relief, transfer of harmful materials out of the Earth's atmosphere, transport of needed materials outside of Earth's atmosphere, capturing and/or filtering airborne particles and other such functions, tasks or combinations thereof. Additionally, the task or function of an airship or group of airships may be changed or altered at any time to fulfill or perform a more desired or necessary task or function.

The foregoing description and accompanying drawings illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

What is claimed is:

1. A method of generating renewable energy, comprising:
launching a plurality of airships into the atmosphere,
positioning the plurality of airships into a location;
coupling the plurality of airships;
collecting solar energy through the use of a solar collection devices disposed on exterior portions of the plurality of airships;
converting the collected solar energy into electrical energy.
storing the electrical energy.

2. The method of claim 1, further comprising:
converting the electrical energy into microwaves.

3. The method of claim 2, further comprising:
transmitting the microwaves to a remote location; and
converting the microwaves into electrical energy.

4. The method of claim 3, wherein the remote location is an airship capable of receiving microwave power transmissions, converting the microwaves into electrical energy and storing the electrical energy.

5. The method of claim 3, further comprising:
transferring the collected electrical energy to a terrestrial electrical energy storage device.

6. The method of claim 3, further comprising:
converting the stored electrical energy into microwaves;
transmitting the microwaves to a satellite;
converting the microwaves into electrical energy in the satellite;
storing the electrical energy in the satellite;
converting the stored electrical energy in the satellite into microwaves; and
transferring the microwaves to a terrestrial facility capable of receiving microwave transmissions.

7. The method of claim 1, wherein the airships are positioned at about 50,000 feet.

8. The method of claim 1, wherein the airships are coupled to form a two dimensional array.

9. The method of claim 1, wherein the solar collection devices comprise solar paint.

10. The method of claim 1, wherein the solar collection devices comprise solar panels.

11. The method of claim 1, wherein the airships are partially filled with carbon dioxide collected from fossil fuel-burning facilities.

12. The method of claim 1, further comprising:
blocking solar rays from hitting earth.

13. A system for generating energy, comprising:
at least one airship with a solar collection device, the at least one airship positioned in the atmosphere and collects and stores solar energy through the use of the solar collection device and a battery.

14. The system of claim 14, further comprising:
coupling the at least one airship with at least a second airship to form an array.

15. The system of claim 14, further comprising:
a remote storage device that receives energy transmitted from the at least one airship.

16. The system of claim 14, wherein the at least one airship is substantially disc-shaped with a length of about 100 feet and a height of about 6 feet.

17. The system of claim 14, wherein the at least one airship includes a propulsion device that can be remotely controlled.

18. The system of claim 14, wherein the at least one airship includes a pump that regulates internal pressure of the airship.

19. The system of claim 14, wherein the solar collection device is solar paint.

20. A system for reducing global warming, comprising:
means for launching a plurality of airships;
means for positioning the plurality of airships;
means for coupling the plurality of airships;
means for collecting solar energy;
means for blocking solar rays;
means for converting solar energy into electrical energy; and
means for transferring the electrical energy into a terrestrial storage device.
